(19) United States
(12) Patent Application Publication
(10) Pub. No.: US 2024/0206131 A1
(43) Pub. Date: Jun. 20, 2024

(54) COOLING APPARATUS, SYSTEM AND METHOD OF MANUFACTURE

(71) Applicant: Katrick Technologies Limited, Glasgow (GB)

(72) Inventor: Karthikeyan Velayutham, Glasgow (GB)

(21) Appl. No.: 18/556,332

(22) PCT Filed: Jul. 28, 2021
(86) PCT No.: PCT/GB2021/051950

§ 371 Date: Oct. 19, 2023

(30) Foreign Application Priority Data
Apr. 19, 2021 (GB) 2105589.2

(51) Int. Cl. H05K 7/20

(52) U.S. Cl. CPC H05K 7/20827; H05K 7/20318; H05K 7/20327

(57) ABSTRACT

A cooling apparatus is disclosed. The cooling apparatus comprises a housing, a first liquid and a second liquid located within the housing. The first liquid has a higher density and lower boiling point than the second liquid. The cooling apparatus further comprises a heat exchanging apparatus to transfer heat to the first liquid to evaporate the first liquid to form a first liquid vapour. The cooling apparatus also comprises a plurality of independent energy dissipating members that extend through the housing. These members move in response to a fluid flow created by the interaction of the first liquid vapour and the second liquid and transfer heat to a volume external to the housing. The cooling apparatus can cool a body whilst drawing minimal or even no electrical power. As such the cooling apparatus is environmentally friendly and cheaper to operate.

The present invention relates to a cooling apparatus, system and method of manufacture. In particular, the described cooling apparatus is suitable for reducing the temperature of an environment which normally employs air conditioning apparatus e.g. a data centre.

### BACKGROUND TO THE INVENTION

A vapour-compression refrigeration system comprises a working fluid which undergoes repeated phase transitions cycling between a liquid and a gas. This type of refrigeration system has numerous applications, ranging from domestic fridges and freezers to air conditioning systems for buildings.

FIG. 1 depicts a vapour-compression refrigeration system 1 known in the art used to cool a data centre 2. The data centre 2 takes the form of a building 3 housing computer systems 4. The temperature within the building 3 is often raised above ambient temperature to, for example, 50° C. due to the operation of the computer systems 4. The purpose of the vapour-compression refrigeration system 1 is to lower the temperature within the building 3 such that the computer systems 4 do not overheat.

High temperature (50° C.) air 5 within the building 3 is drawn into circulation loop 6, by means of a circulation fan 7. Whilst traversing the circulation loop 6, the high temperature air 5 passes through an evaporator 8 and loses heat. The resulting low temperature air 9 with a temperature of 25° C. is pumped into the building 3.

The evaporator 8 is part of a sealed refrigeration loop 10 which contains a working fluid 11, commonly known as a refrigerant. The evaporator 8 transfers heat from the high temperature air 5 to the working fluid 11. As such, the evaporator 8 can more generally be considered a heat exchanging apparatus. The heat induces a phase change in the working fluid 11 from a liquid to a gas. The gaseous working fluid 11 circulates about the refrigeration loop 10 where it is then compressed by a compressor 12 resulting in a temperature increase of the gaseous working fluid 11 up to, for example, 65° C. The hot (65° C.) compressed working fluid 11 is then cooled in a condenser 13 such that the gaseous working fluid 11 expels heat and condenses back to a liquid, resulting in a liquid compressed working fluid 11 with a reduced temperature of, for example, 35° C. After which, the temperature of the liquid working fluid 11 is reduced further to, for example, −30° C. by reducing the pressure of the liquid compressed working fluid 11 by means of an expansion valve 14. The cold (−30° C.) uncompressed working fluid is recirculated into the evaporator where, by means of thermal diffusion, heat again transfers from the high temperature air 5 to the working fluid 11. The cycle repeats continually cooling the high temperature air 5 originating from the building 3.

The vapour-compressed refrigeration system 1 as depicted in FIG. 1 requires electrical power to operate. In particular, the circulating fan 7, compressor 12 and condenser 13 all draw electrical power. Disadvantageously, such systems 1 can draw significant amounts of electrical power. A relatively large data centre can equate to electrical power requirements equivalent to a town. Such a large electrical power consumption is expensive and also has a significant environmental impact.

Another disadvantage of the vapour-compressed refrigeration system 1 is that all the components, in particular the circulating fan 7, compressor 12 and condenser 13, require maintenance. This is an additional financial burden and the vapour-compressed refrigeration system 1 cannot operate during the required maintenance breaks.

### SUMMARY OF THE INVENTION

It is an object of an aspect of the present invention to provide a cooling system that obviates or at least mitigates one or more of the aforesaid disadvantages of the cooling systems known in the art.

According to a first aspect of the present invention there is provided a cooling apparatus comprising:
a housing;
a first liquid and a second liquid located within the housing, the first liquid having a higher density and lower boiling point than the second liquid;
a heat exchanging apparatus to transfer heat to the first liquid to evaporate the first liquid to form a first liquid vapour; and
a plurality of independent energy dissipating members that extend through the housing, wherein the independent energy dissipating members move in response to a fluid flow created by the interaction of the first liquid vapour and the second liquid and transfer heat to a volume external to the housing.

The independent energy dissipating members are termed independent as each member is not mechanically coupled to any other member. Both ends of each member are free to move. The independent energy dissipating members move randomly relative to each other.

Preferably, the housing comprises a unitary chamber. Alternatively, the housing comprises two or more chambers with one or more pipes connecting the two or more chambers.

Most preferably, the housing is sealable. The cooling apparatus is a closed cooling apparatus. In this arrangement the first and or second liquids are not added and or removed during operation.

Preferably, the first and second liquids occupy an interior volume of the housing. The first and second liquids may mix within the interior volume of the housing.

Preferably, the first liquid is located within a first portion of the housing. The second liquid is located within a second portion of the housing.

Most preferably, the first liquid is 1-Chloro-3,3,3-trifluoropropene (R1233ZD) and the second liquid is de-mineralised water. Alternatively, the first liquid is Dichlorotrifluoroethane and the second liquid is de-mineralised water. Alternatively, the first liquid is 1,2-Dichlorotetrafluoroethane and the second liquid is de-mineralised water. Alternatively, the first liquid is 1,1,1,3,3,3-Hexafluoropropane and the second liquid is de-mineralised water. Alternatively, the first liquid is R1234 YF and the second liquid is de-mineralised water. Alternatively, the first liquid is R-1234ze (Trans-1,3,3,3-tetrafluoroprop-1-ène) and the second liquid is de-mineralised water.

Optionally, the cooling apparatus may comprise three or more liquids.

Most preferably, the heat exchanging apparatus to transfer heat to the first liquid to evaporate the first liquid to form a first liquid vapour may comprise one or more pipes, more specifically, one or more coiled pipes. The one or more pipes may pass from a base end of the housing to a top end of the housing.

Additionally, or alternatively, the heat exchanging apparatus may comprise the first portion of the housing.

Additionally, or alternatively, the heat exchanging apparatus may comprise one or more conductive members.

Additionally, or alternatively, the heat exchanging apparatus may comprise a fluid tight casing.

Additionally, or alternatively, the heat exchanging apparatus may comprise an evaporator.

Optionally, the cooling apparatus may further comprise one or more pellets. The one or more pellets are located within the interior volume of the cooling apparatus. The one or more pellets are suspended within the first liquid and or second liquid. The density of the one or more pellets is between the density of the first liquid and second liquid. The pellets are chemically unreactive with the first liquid, second liquid, and or first liquid vapour.

Preferably, the pellets are magnetically neutral.

Most preferably, the plurality of independent energy dissipation members may take the form of a plurality of rods. Each rod of the plurality of rods may comprise a first end, a second end and a central mounting portion between the first and second ends. Each rod extends through the housing. The first end of each rods extends into the interior volume of the housing. The second end extends into the volume external to the housing. The mounting portion of each rod is mounted to the housing.

Preferably, the plurality of rods may be uniformly distributed about the housing. Alternatively, the plurality of rods may be non-uniformly distributed about the housing.

Preferably, the plurality of rods may be orientated perpendicular to the housing. Alternatively, the plurality of rods may be orientated non-perpendicular to the housing.

Preferably, the first end of each rod of the plurality of rods comprises an enlarged region with at least one conductive surface. Similarly, the second end of each rod of the plurality of rods comprises an enlarged region with at least one conductive surface. The conductive surfaces facilitate absorbing and dissipating thermal energy.

Preferably, the plurality of rods may comprise the same material composition. The plurality of rods may comprise copper. Copper has a high thermal conductivity.

Optionally, the plurality of rods may comprise a protective coating.

Preferably, the plurality of rods may be uniform in dimension, design and material composition. Alternatively, the plurality of rods may be non-uniform dimension, design and material composition.

Preferably, the housing may comprise an inlet port and an outlet port. The inlet and outlet ports are preferably sealable.

Optionally, the cooling apparatus further comprises a condensing loop. The condensing loop condenses the first liquid vapour and returns the first liquid to the first portion of the housing.

Optionally, the cooling apparatus further comprises a sink. The sink may comprise the first liquid. The sink is preferably connected to the housing. The sink maintains the level of the first liquid within the first portion of the housing.

Optionally, the cooling apparatus further comprises a pumping system. The pumping system pumps the first and second liquid into and out of the housing.

Optionally, the cooling apparatus further comprises one or more storage tanks. The one or more storage tanks are connected to the pumping system.

Optionally, the cooling apparatus may further comprise one or more compressors. The cooling apparatus may further comprise a relief valve. The cooling apparatus may further comprise an expansion valve. The cooling apparatus may further comprise a separator with a drain.

According to a second aspect of the present invention there is provided a cooling system comprising a cooling apparatus in accordance with the first aspect of the present invention, and a body to be cooled.

Optionally, the cooling system may further comprise a heat transfer apparatus.

Optionally, the heat transfer apparatus may comprise a circulation loop. The heat transfer apparatus may further comprise a circulation fan.

Optionally, the circulation loop may comprise air. The circulation loop circulates air from the body to the cooling apparatus. The circulation loop transfers high temperature air from the body to the cooling apparatus. The cooling apparatus cools the high temperature air.

Alternatively, the circulation loop may comprise a fluid. The fluid is sealed within the circulation loop. The fluid passes through the body or cooling apparatus but does not mix any fluid external to the circulation loop. The fluid absorbs heat from the body. The circulation loop circulates the fluid to the cooling apparatus which cools the fluid. The fluid may be a refrigerant.

Alternatively, the circulation loop may comprise a first loop with a first fluid and a second loop with a second fluid. The first fluid is sealed within the first loop. The second fluid is sealed within the second loop. The first fluid absorbs heat from the body. The first loop circulates the first fluid to a heat exchanger. The heat exchanger transfers heat from the first fluid to the second fluid. The second loop circulates the second fluid to the cooling apparatus which cools the second fluid. The first and second fluids may be the different or the same.

Optionally, the heat transfer apparatus may comprise one or more conductive members. The first end of the one or more conductive members is thermally connected to the body. The second end of the one or more conductive members is thermally connected to the cooling apparatus. The second end of the one or more conductive members extends through the housing into the interior volume of the cooling apparatus. The conductive members comprise pure copper. The conductive members transfer heat by thermal diffusion from the body to the cooling apparatus. The second end of the one or more conductive members act as the heat exchanging apparatus of the cooling apparatus.

Optionally, the cooling apparatus may be located above the body. Convection within the body transfers high temperature air to the cooling apparatus.

Optionally, the body may also be the cooling apparatus. The body may comprise the features of the cooling apparatus.

Optionally, the cooling system may further comprise a refrigeration loop with a working fluid. The refrigeration loop comprises the cooling apparatus. In other words, the cooling apparatus is a component of the refrigeration loop. The refrigeration loop further comprises an evaporator, compressor, and expansion valve.

Optionally, both the refrigeration loop and circulation loop pass through the cooling apparatus.

Embodiments of the second aspect of the invention may comprise features to implement the preferred or optional features of the first aspect of the invention or vice versa.

According to a third aspect of the present invention there is provided a method of manufacturing a cooling apparatus comprising,
providing a housing
providing a first liquid and a second liquid located within the housing, the first liquid having a higher density and lower boiling point than the second liquid;
providing a heat exchanging apparatus to transfer heat to the first liquid to evaporate the first liquid to form a first liquid vapour; and
providing a plurality of independent energy dissipating members that extend through the housing, wherein the independent energy dissipating members move in response to a fluid flow created by the interaction of the first liquid vapour and the second liquid and transfer heat to a volume external to the housing.

Preferably, the method of manufacturing a cooling apparatus may further comprise determining the characteristics of a body to be cooled by the cooling apparatus.

Preferably, determining the characteristics of the body may comprise determining the temperature of the body without any cooling, a target temperature of the body with cooling, the temperature variability of the body, the dimensions, shape, composition, location and accessibility of the body.

Preferably, the method of manufacturing a cooling apparatus may further comprise determining optimum parameters of a cooling apparatus for use with the body.

Preferably, determining the optimum parameters of a heat cooling apparatus for use with the body may further comprise utilising the characteristics of the body.

Preferably, determining the optimum parameters of a cooling apparatus may comprise determining: the dimensions and shape of the cooling apparatus; the volume, relative ratio and chemical composition of the first and second liquids; the distribution, orientation, dimensions, design and material composition of the rods; if one or more pellets are required, if a condensing loop is required; if a sink is required; if one or more storage tanks are required; the form of the heat exchanger; and how to cooling apparatus is to be integrated into a cooling system.

Embodiments of the third aspect of the invention may comprise features to implement the preferred or optional features of the first and or second aspect of the invention or vice versa.

According to a fourth aspect of the present invention there is provided a method of manufacturing a cooling system comprising,
providing a cooling apparatus in accordance with the third aspect of the present invention; and
providing a body to be cooled.

Optionally, the method of manufacturing a cooling system further comprises providing a circulation loop.

Optionally, the method of manufacturing a cooling system may further comprise providing conductive members.

Optionally, the method of manufacturing a cooling system may comprise locating the cooling apparatus above the body.

Optionally, providing the cooling apparatus may comprise modifying the body to be cooled to comprise the features of the cooling apparatus.

Optionally, the method of manufacturing a cooling system further comprises providing a refrigeration loop.

Embodiments of the fourth aspect of the invention may comprise features to implement the preferred or optional features of the first, second and or third aspects of the invention or vice versa.

### BRIEF DESCRIPTION OF DRAWINGS

There will now be described, by way of example only, various embodiments of the invention with reference to the drawings, of which:

FIG. 1 presents a schematic representation of a cooling system known in the art;

FIG. 2 presents a schematic representation of a cooling system in accordance with an embodiment of the present invention;

FIG. 3 presents a schematic cross-sectional view of a cooling apparatus employed within the cooling system of FIG. 2;

FIG. 4 presents a cutaway perspective view of the cooling apparatus of FIG. 3;

FIG. 5 presents a perspective view of a rod employed within the cooling apparatus of FIG. 3;

FIG. 6 presents a schematic cross-sectional view of an alternative embodiment of the cooling apparatus of FIG. 3;

FIG. 7 presents a schematic representation of an alternative embodiment of the cooling system of FIG. 2;

FIG. 8 presents a schematic representation of a further alternative embodiment of the cooling system of FIG. 2;

FIG. 9 presents a schematic representation of yet another alternative embodiment of the cooling system of FIG. 2;

FIG. 10 presents a schematic representation of an alternative embodiment of the cooling system of FIG. 2;

FIG. 11 presents a schematic representation of an alternative embodiment of the cooling system of FIG. 2;

FIG. 12 presents a schematic representation of an alternative embodiment of the cooling system of FIG. 2;

FIG. 13 presents a schematic representation of an alternative embodiment of the cooling system of FIG. 2;

FIG. 14 presents a schematic representation of an alternative embodiment of the cooling system of FIG. 2;

FIG. 15 presents a schematic representation of an alternative embodiment of the cooling system of FIG. 2;

FIG. 16 presents a flow chart of the method of manufacturing the cooling apparatus of FIG. 2;

In the description which follows, like parts are marked throughout the specification and drawings with the same reference numerals. The drawings are not necessarily to scale and the proportions of certain parts have been exaggerated to better illustrate details and features of embodiments of the invention.

### DETAILED DESCRIPTION OF THE PREFERRED EMBODIMENTS

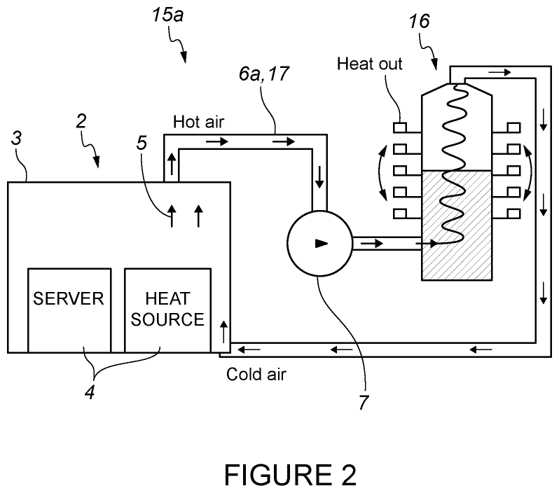

An explanation of the present invention will now be described with reference to FIGS. 2 to 16.

### Cooling System

FIG. 2 depicts a cooling system 15a suitable for cooling a data centre 2 which takes the form of computer systems 4 housed within a building 3. The cooling system 15 comprises a cooling apparatus 16 and a heat transfer apparatus to transfer heat from the data centre 2 to the cooling apparatus 16. In the embodiment of FIG. 2, the heat transfer apparatus takes the form of a circulation loop 6a and a circulation fan 7. The circulation fan 7 draws high temperature air 5 within the building 3 about the circulation loop 6a to the cooling apparatus 16.

More specifically, the circulation loop 6a comprises pipes 17 which channel high temperature air 5 to the cooling apparatus 16. The cooling apparatus 16 cools the high temperature air 5 resulting in low temperature air 9. The low temperature air 9 is circulated about the circulation loop 6a into the building 3 and cools the computer systems 4.

### Cooling Apparatus

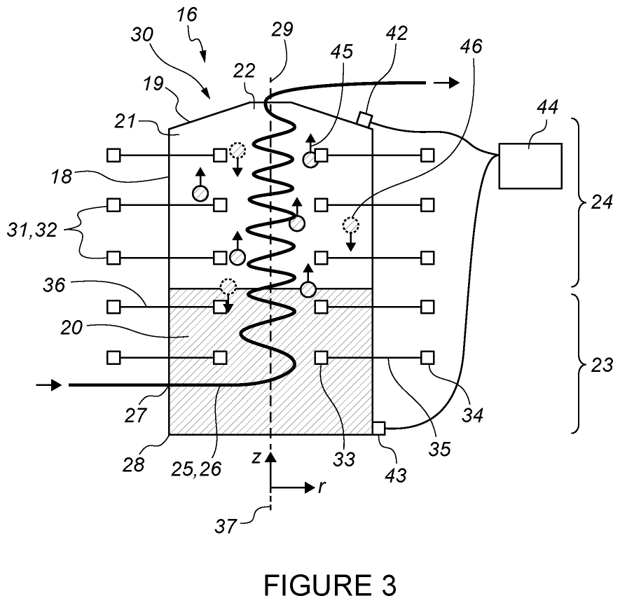

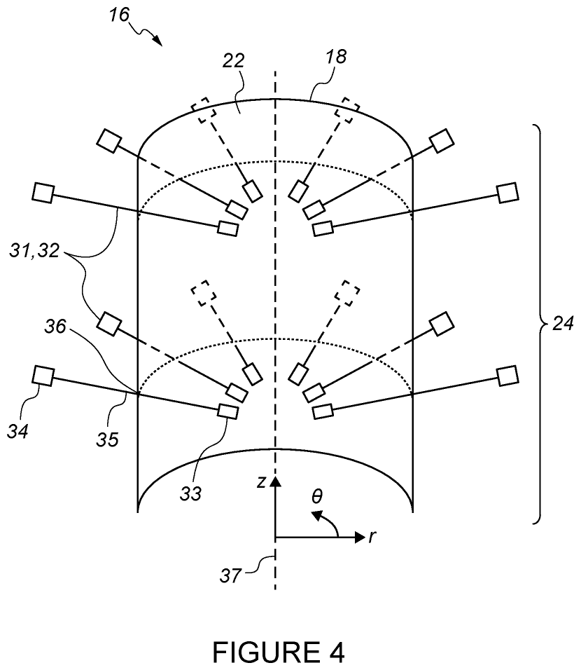

As can clearly be seen in FIGS. 2 to 4, the cooling apparatus 16 comprising a substantially cylindrical, sealable housing 18 with a substantially conical lid 19. The housing 18 comprises stainless steel, specifically, SA516 GR.65. For ease of understanding, FIGS. 3 and 4 depict a cylindrical coordinate system with r, θ, and z axes.

The cooling apparatus 16 can be seen to comprise a first liquid 20 and a second liquid 21 both of which are located within the housing 18. The first and second liquids 20, 21 occupy an interior volume 22 of the housing 18. The first liquid 20 has a higher density but lower boiling point in comparison to the second liquid 21. As such, whilst the first and second liquids 20, 21 are free to mix within the housing 18, the first liquid 20 locates within a first portion 23 of the housing 18, at the base of the housing 18, and the second liquid 21 locates within a second portion 24 of the housing 18, above the first liquid 20.

By way of example, the first liquid 20 may be trans-1-chloro-3,3,3-trifluoroprop-1-ene (R1233ZD), also referred to as trans chloro trifluoropropene, and the second liquid 21 may be de-mineralised water. The density of R1233ZD is approximately 1.3 times that of de-mineralised water and R1233ZD has a boiling point of 18.3° C. which is lower than the boiling point of demineralised water, 100° C. A cooling apparatus 16 comprising R1233ZD and de-mineralised water as the first and second liquids 20, 21 is suitable for cooling high temperature air 5, over 19° C., from a data centre 2. For the cooling apparatus 16 to operate, both the first and second liquids 20, 21 are required to be in liquid form at ambient temperature. As such, the ambient temperature of the environment surrounding the cooling apparatus 16 should be below the boiling point of the first and second liquids 20, 21, in this case, below 18.3° C.

Further examples of the first and second liquids 20, 21 are provided in Table I along with an operating temperature range of a cooling apparatus 16 comprising the first and second liquids 20, 21. The combinations of the first and second liquids 20, 21 may be suited to different operational temperature ranges and system configurations. It will be appreciated that different operating temperature ranges to those detailed in Table I could be achieved by using different first and second liquids 20, 21 and different combinations of the first and second liquids 20, 21 beyond the disclosed liquids and combinations in Table I.

TABLE I
Examples of: the first liquid; second liquid; a temperature range
of the uncooled high temperature air suitable to be cooled by a cooling
apparatus comprising the first and second liquids; example of uses
of a cooling apparatus comprises the first and second liquid.

| | | Operating | |
|---|---|---|---|
| | | Temperature | |
| First Liquid | Second Liquid | Range (° C.) | Examples of Uses |
| 1-Chloro-3,3,3- | De-mineralised water | Over 19° C. | Data centres, air |
| trifluoropropene (Trans | | | conditioners, cooling |
| chloro trifluoropropene) | | | rooms |
| R1233ZD | | | |
| (Boiling point: 18.3° C.) | | | |
| Dichlorotrifluoroethane | De-mineralised water | Over 28° C. | Data centres, air |
| (Boiling point: 27.6° C.) | | | conditioners, cooling |
| | | | rooms |
| 1,2-Dichlorotetrafluoroethane | De-mineralised water | Over 4° C. | Super cooled data |
| (Boiling point: 3.5° C.) | | | centres, air |
| | | | conditioners, |
| | | | supercooling rooms |
| 1,1,1,3,3,3- | De-mineralised water | Over 0° C. | Super cooled data |
| Hexafluoropropane | | | centres, air |
| (Boiling point: −1.7° C.) | | | conditioners, |
| | | | supercooling rooms |
| R1234 YF | De-mineralised water | Over −20° C. | Freezer cycle, freezers |
| (Boiling point: −29.29° C.) | | | |
| R-1234ze - (Trans-1,3,3,3- | De-mineralised water | Over −18° C. | Freezer cycle, freezers |
| tetrafluoroprop-1-ène) | | | and low-temperature |
| (Boiling point: −18.89° C.) | | | chillers |

The cooling apparatus 16 also comprises a heat exchanging apparatus 25 which transfers heat from the high temperature air 5 to the first liquid 20 (and second liquid 21) in order to evaporate a quantity of the first liquid 20. The first and second liquids 20, 21 are not directly exposed to the high temperature air 5 or any external fluid carrying heat from the data centre 2. In the embodiment of FIGS. 2 and 3, the heat exchanging apparatus 25 takes the form of a coiled pipe 26 extending along the z axis of the cooling apparatus 16. More specifically, the coiled pipe 26 is located within the interior volume 22 of the housing 18. The coiled pipe 26 can be considered a portion of the air circulation loop 6a that directs high temperature air 5 through the cooling apparatus 16. The coiled pipe 26 comprises an inlet 27 towards the base end 28 of the housing 18 and an outlet 29 towards a top end 30 of the housing 18, in the conical lid 19.

The cooling apparatus 16 further comprises a plurality of independent energy dissipation members 31. As can be clearly seen in FIGS. 3 to 5, the plurality of independent energy dissipation members 31 take the form of rods 32. Each rod 32 comprises a first end 33, a second end 34 and a central mounting portion 35 between the first and second ends 33, 34. Each rod 32 extends through the housing 18. More specifically, the central mounting portion 35 of each rod 32 is mounted to the housing 18 by means of a bearing 36. The first end 33 of the each rod 32 extends into the interior volume 22 of the housing 18 towards a central axis 37 of the housing 18. The second end 34 is located external to the housing 18, extending radially away from the central axis 37 of housing 18. The first and second ends 33, 34 of each rod 32 are free to move. The bearing 36 translates any movement from the first end 33 to the second end 34 of each rod 32 (and vice versa). The rods 32 are independent in that each rod 32 is not mechanically coupled to any of the other rods 32. As such, the rods are independent and can move randomly relative to each other.

The rods 32 are distributed about of the housing 18 in both θ and z directions. The rods 32 are predominately located in the second portion 24 of the housing 18. FIGS. 2 to 4 depict the rods 32 as being uniformly distributed about the housing 18, orientated perpendicular to the housing 18 and all of uniform dimensions such as length.

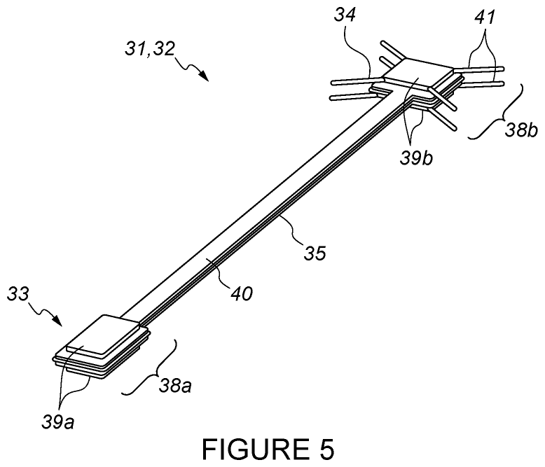

As can be seen from FIG. 5 which depicts one of the rods 32, both the first and second ends 33, 34 comprise enlarged regions 38a, 38b with thermally conductive surfaces 39a, 39b. The thermally conductive surfaces 39a located on the enlarged region 38a at the first end 33 facilitate absorbing thermal energy by thermal diffusion from the liquids 20, 21 contained within the housing 18. The absorbed thermal energy can conduct along the rod 32 to the second end 34. The thermally conductive surfaces 39b located on the enlarged regions 38b at the second end 34 facilitate dissipating the thermal energy to the external surroundings of the cooling apparatus 16 through thermal diffusion. The thermally conductive surfaces 39a, 39b are made of the same material as the bulk of the rods 32. The rods 32 may comprise a protective coating 40 which covers all but the thermally conductive surfaces 39a, 39b. It will be appreciated the thermally conductive surfaces 39a, 39b may be made of a different material such as pure copper which has a high thermal conductivity.

The rods 32 depicted in FIG. 5, further comprises thermally conductive protrusions 41 protruding from the thermally conductive surfaces 39b at the second end 34. The thermally conductive protrusions 41 increase the surface area of the thermally conductive surfaces 39b and so increase the thermal energy dissipation capacity of the second end 34 of the rod 32.

It will be appreciated the dimensions, design, and composition of the rods 32 can be optimised to achieve the desired thermal dissipation properties. For example, the length of the rods 32, dimensions of the enlarged regions 38a, 38b, the thermally conductive surfaces 39a, 39b and or the inclusion of the thermally conductive protrusions 41 can be varied to increase or decrease the thermal dissipation properties of the rods 32.

The rods 32 are configured to operate randomly relative to each other. It will be further be appreciated the dimensions, design and material composition of each rod 32 may vary. Variations in the rods 32 may contribute to the relative random movement of the rods 32.

The housing 18 comprises a sealable inlet port 42 and a sealable outlet port 43. The sealable inlet port 42 is located at a top end 30 of the housing 18, through the second portion 24 of the housing 18 and provides a means for adding the first and second liquids 20, 21 into the housing 18. Similarly, the sealable outlet port 43 is located, at a base end 28 of the housing 18, through the first portion 23 of the housing 18 and provides a means for draining the first and second liquids 20, 21 from the housing 18. In order to fill and maintain the housing 18 at a positive pressure, the first and second liquids 20, 21 may be pumped to and from the housing 18 by a pumping system 44.

FIG. 3 shows the cooling apparatus 16 of FIG. 2 in operation, in other words cooling the high temperature air 5. The cooling apparatus 16 is a closed device such that the first and second liquids 20, 21 are not added or removed during operation. The heat exchanging apparatus 25, in other words the coiled pipe 26, transfers heat to the first liquid 20. As such, a portion of the first liquid 20 evaporates to form a first liquid vapour. The first liquid vapour takes the form of gaseous bubbles 45. The gaseous bubbles 45 have a lower density than both the first liquid 20 and the second liquid 21. As such, the gaseous bubbles 45 move in the positive z-direction, into the second portion 24 of the housing 18 and through the second liquid 21. The thermal energy from the high temperature air 5 is converted into kinetic energy in the form of the motion of the gaseous bubbles 45.

The interaction, in the form of relative motion and or thermal gradients, of the gaseous bubbles 45 and the second liquid 21 creates a fluid flow. More specifically, the fluid flow includes the flow of the first liquid 20, second liquid 21 and gaseous bubbles 45. For example, the fluid flow is depicted by the arrows in FIG. 3. This fluid flow may be Laminar and or turbulent. The fluid flow induces the first end 33 of the rods 32 to move, oscillate and or vibrate. As such, the kinetic energy of the gaseous bubbles 45 is converted into mechanical energy. The Laminar fluid flow of the gaseous bubbles 45 may result in the gaseous bubbles 45 directly colliding with the first ends 33 of the rods 32, deflecting the rods 32. Furthermore, the turbulent fluid flow of the gaseous bubbles 45 and second liquid 21 may induce movement and or mechanical vibrations within the first ends 33 of the rods 32.

Each gaseous bubble 45 dissipates kinetic and thermal energy. As a result, each gaseous bubble 45 will eventually condense to form a liquid bubble 46 of the first liquid 20. The liquid bubbles 46 sink back towards the base end 28, into the first portion 23 of the housing 18 as the density of the liquid bubbles 46 is greater than the density of the second liquid 21. An advantage of the liquid bubbles 46 sinking back through the second portion 24 of the housing 18, is the liquid bubbles 46 may further create fluid flows and induce movement and or mechanical vibrations within the rods 32.

The motion induced in the first ends 33 of the rods 32 is transmitted by means of the bearing 36 to the second ends 34 of the rods 32. The heat absorbed by the first ends 33 of the rods 32 conducts along the rods 32 to the second ends 34. The mechanical and thermal energy at the second ends 34 of the rods 32 is dissipated to the surroundings of the cooling apparatus 16. As such, the cooling apparatus 16 cools the high temperature air 5. The resulting low temperature air 9 is circulated into the building 3 and cools the computer systems 2 of the data centre 2.

As an alternative embodiment, instead of being cylindrical, it will be appreciated that the housing 18 could take any regular or non-regular three-dimensional shape.

As an additional or alternative embodiment, it will be appreciated the cooling apparatus 16 comprises a third liquid. The cooling apparatus 16 may comprise multiple liquids.

As an additional or alternative embodiment, the distribution of the rods 32 about the housing 18 may be non-uniform. As another additional or alternative embodiment, the rods 32 may be orientated non-perpendicular to the housing 18. As a further additional or alternative embodiment, the dimensions, design, material composition, distribution, and orientation of the rods 32 may be computationally optimised.

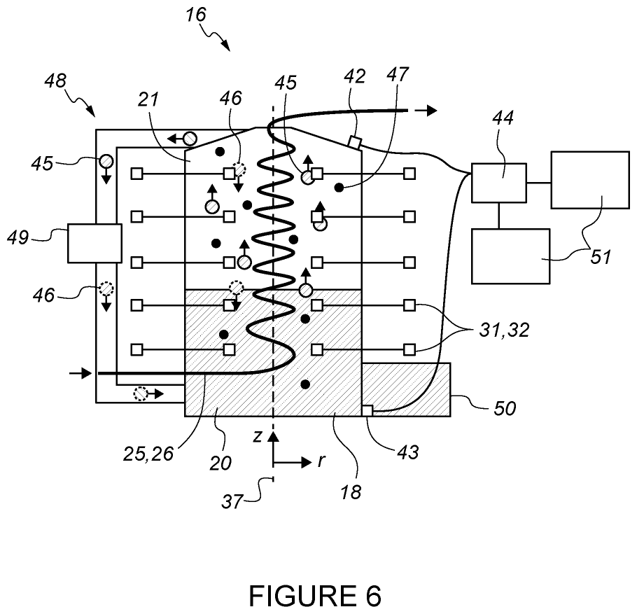

As an additional or alternative feature, the cooling apparatus 16 further comprises pellets 47. As can be seen in FIG. 6, the pellets 47 are located within the interior volume 22 of the cooling apparatus 16 suspended within the first and second liquids 20, 21. The pellets 47 move about the interior volume 22 of the housing 18 in response to the fluid flow created by the interaction of the gaseous bubbles 45 and the second liquid 21. The pellets 47 collide with the rods 32 inducing further movement, or more specifically, mechanical vibrations within the rods 32, in addition to the movement induced directly by the fluid flow. The density of the pellets 47 is between the density of the first and second liquids 20, 21 such that the pellets 47 are not too heavy or buoyant when suspended within the first and second liquids 20, 21. Furthermore, the pellets 47 are chemically unreactive with the first liquid 20, second liquid 21 and gaseous bubbles 45. The pellets 47 are also preferably magnetically neutral. The dimensions and material composition of the pellets 47 may be optimised to achieve the desired interaction with the fluid flow.

As an additional or alternative embodiment, the cooling apparatus 16 of FIG. 6, further comprises a condensing loop 48 with a condenser 49. Instead of the gaseous bubbles 45 passively condensing once they have lost sufficient energy within the housing 18, the condensing loop 48 actively condenses the gaseous bubbles 45. More specifically, once the gaseous bubbles 45 have traversed through the second portion 24 of the housing 18, the gaseous bubbles 16 pass through the condensing loop 48 where the condenser 49 actively cools the gaseous bubbles 45 such that they condense to liquid bubbles 46. The liquid bubbles 46 are returned to the first portion 23 of the housing 18. A condensing loop 48 may be advantageous if, for example, the cooling apparatus 16 is over heated such that the gaseous bubbles 45 accumulate at the top end 30 of the housing 18 and the level of the first liquid in the housing 18 decreases.

As another additional or alternative feature, the cooling apparatus 16 of FIG. 6 further comprises a sink 50 of the first liquid 20. The sink 50 is connected to the housing 18 and maintains the level of the first liquid 20 within the first portion 23 of the housing 18. As the first liquid 20 evaporates within the cooling apparatus 16, this may induce non negligible changes in pressure and or volume within the cooling apparatus 16. The sink 50 minimises any changes in pressure and or volume.

As another additional or alternative feature, the cooling apparatus 16 of FIG. 6 further comprises storage tanks 51. Each storage tank 51 comprises a different liquid such as those listed in Table 1 and the storage tanks are connected to the pumping system 44. The liquids may be compressed for storage within the storage tanks 51. The pumping system 44 facilitates removing the first and second liquids 20, 21 from the housing 18 to be stored within the respective storage tanks 51. The pumping system 44 can also facilitate replacing the first and second liquids 20, 21 with alternative combinations of liquids. As such, the combination of the first and second liquid 20, 21 can be optimised according to the operation conditions of the cooling apparatus 16. The process of removing and replacing the first and second liquids 20, 21 according to the operation requirements may be automated by the pumping system 44. As such the pumping system 44 may comprise sensors to monitor the cooling apparatus 16 and the surrounding conditions. Whilst FIG. 6 depicts two storage tanks 51 it will be appreciated there may be a plurality of storage tanks 51 offering numerous alternative combinations of first and second liquids 20, 21.

The process of heat transfer to the first liquid 20, evaporation of the first liquid 20 to form gaseous bubbles 45, mechanical and thermal energy transfer from the gaseous bubbles 45 to the energy dissipation member (in other words the rods 32) and condensation of the gaseous bubbles 45 to form liquid bubbles 46 is repeated forming a cycle. The mechanical and thermal energy is continually dissipated by the cooling apparatus 16.

A key advantage of the cooling system 15a is that it requires less electrical energy to operate. In the embodiment of FIG. 2, electrical power is only required to operate the circulation fan 7. The cooling system 15a does not comprise a compressor or a condenser. As such, the cooling system 15a cools the computer systems 4 of the data centre 2 using less electrical energy than conventional systems 1 known in the art. As such, the cooling system 15a is environmentally friendly. It is noted, the cooling apparatus can operate without drawing any electrical power. As such, the cooling apparatus 16 may be considered a passive component.

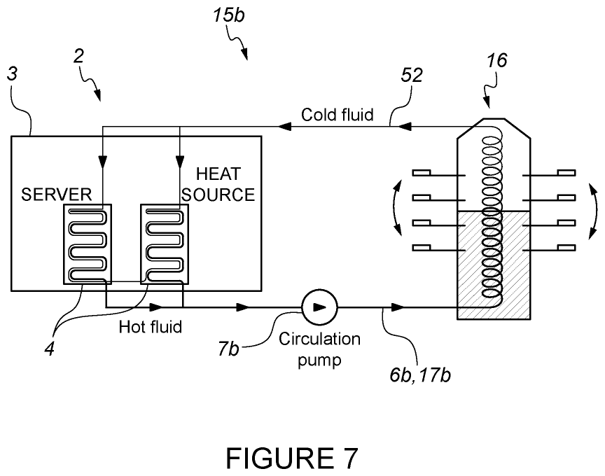

FIG. 7 depicts an alternative cooling system 15b which may comprise the same preferable and optional features as the cooling system 15a as depicted in FIGS. 2 to 6.

However, instead of the circulation loop 6a of FIG. 2, the heat transfer apparatus of the cooling system 15b of FIG. 7 takes the form of a circulation loop 6b sealed within which is a fluid 52. The circulation loop 6b comprises pipes 17b which channel the fluid 52 to the computer systems 4. Heat is transferred from the computer systems 4 to the fluid 52 within the circulation loop 6b.

The pipes 17b in the vicinity of the computer systems 4 act as a heat exchanging apparatus and may be arranged to maximise the heat transfer from the computer systems 4 to the fluid 52. For example, the pipes 17b zigzag back and forth so as to take multiple passes by the computer systems 4, increasing the time the fluid 52 is exposed to the computer systems 4 and so maximising the heat transferred to the fluid 52.

A circulation pump 7b circulates the heated fluid 52 through the pipes 17b of the circulation loop 6b towards a cooling apparatus 16. The cooling apparatus 16 cools the heated fluid 52 and the resulting cooled fluid 52 is circulated back towards the computer systems 4 to absorb more heat. The process of absorbing heat from the computer systems 4, transferring the heat to the cooling apparatus 16 and dissipating the heat by means of the cooling apparatus 16 is repeated resulting in the continual cooling the computer systems 4

The fluid 52 sealed within the circulation loop 6b does not mix with air external to the circulation loop 6b such as air contained within the building 3. The fluid 52 can be any suitable fluid such as a refrigerant known in the art.

An advantage of the circulation loop 6b is that the fluid 52 may be as chosen according to the operational parameters of the cooling system 15b, for example the operational temperature range. Whilst the fluid 52 of the circulation loop 6b could be air, in contrast to circulation loop 6a, the circulation loop 6b is not limited to circulating air. As such, the fluid 52 of the circulation loop 6b may have desirable thermal and chemical properties to enhance the cooling system 15b. Furthermore, it may be financially more favourable to operate with a particular fluid 52 instead of air. In particular, the fluid 52 of the circulation loop 6b may not demand relatively more expensive, higher pressure apparatus required for operating with air.

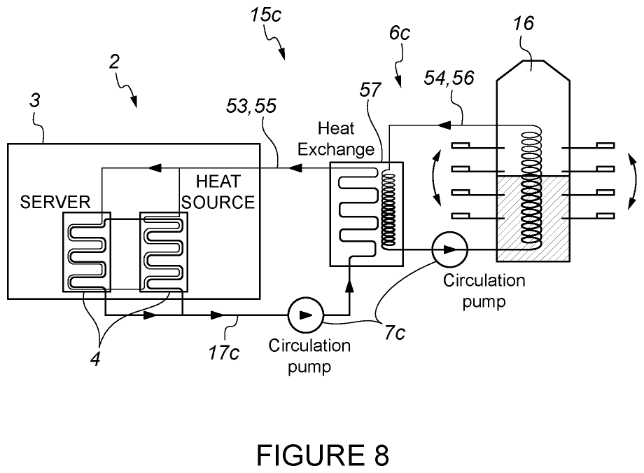

FIG. 8 depicts an alternative cooling system 15c which may comprise the same preferable and optional features as the cooling systems 15a, 15b depicted in FIGS. 2 to 7.

However, instead of the circulation loops 6a, 6b of FIGS. 2 and 7, the heat transfer apparatus of the cooling system 15c of FIG. 8 takes the form of a circulation loop 6c with a first loop 53 and a second loop 54. The first loop 53 comprises a first fluid 55. The first fluid 55 is sealed within the first loop 53. Similarly, the second loop 54 comprises a second fluid 56. The second fluid 56 is sealed within the second loop 54. The first and second fluids 55, 56 do not mix with each other nor air external to the circulation loop 6c. The first and second fluids 55, 56 are circulated about the first and second loops 53, 54 by circulation pumps 7c.

Heat from the computer systems 4 is transferred to the first fluid 55 of the first loop 53. Similar to the second embodiment of FIG. 7, pipes 17c of the first loop 53 located in the vicinity of the computer systems 4 act as a heat exchanging apparatus and may be arranged to maximise the heat transfer from the computer systems 4 to the first fluid 55.

The first loop 53 transfers the heated first fluid 55 to a heat exchanging apparatus 57. The heat exchanging apparatus 57 transfers heat from the first fluid 55 of the first loop 53 to the second fluid 56 of the second loop 54. The second loop 54 transfers the heated second fluid 56 to a cooling apparatus 16 which cools the heated second fluid 56. The resulting cooled second fluid 56 is circulated back within the second loop 54 to the heat exchanging apparatus 57 where it cools the heated first fluid 55. Then, the cooled first fluid 55 is circulated back within the first loop 53 to computer systems 4 to repeat the cycle and reabsorb heat thereby continually cooling the computer systems 4.

The first and second fluids 55, 56 of the first and second loops 53, 54 may be the same or different. Again, like the second embodiment of FIG. 7, the first and second fluids 55, 56 may be chosen according to the operation parameters of the cooling system 15c.

Advantageously, the cooling system 15c of FIG. 8 is particularly suited for retrofitting existing cooling systems known in the art with a cooling apparatus 16. The first loop 53 of FIG. 8 may exist as part of cooling systems known in art. As such, when retrofitting, only the second loop 54 and cooling apparatus 16 needs to be introduced. This can save considerable expense and time.

It will be appreciated that the circulation loop 6c of FIG. 8 may additionally comprise a third loop and more generally a plurality of loops. Additional loops in conjunction with heat exchanging apparatus may help connect multiple data centres 2 and or multiple cooling apparatus 16 to the cooling system 15c.

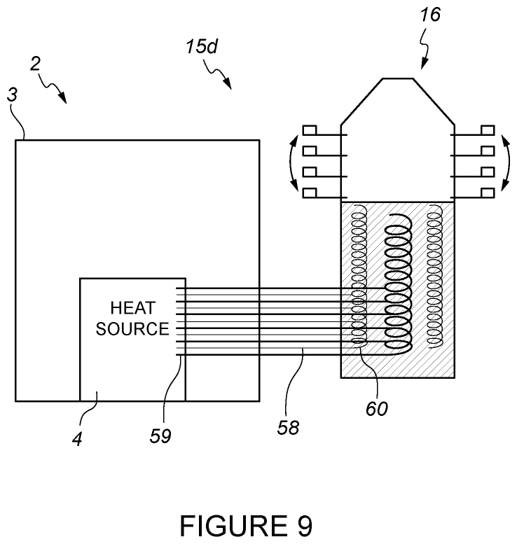

FIG. 9 depicts a further alternative cooling system 15d which may comprise the same preferable and optional features as the cooling systems 15a, 15b, 15c depicted in FIGS. 2 to 8.

Instead of the circulation loops 6a, 6b, 6c of FIGS. 2 and 8, the heat transfer apparatus of the cooling system 15d of FIG. 9 takes the form of conductive members 58, each conductive member 58 thermally connected at a first end 59 directly to the computer systems 4 and at a second end 60 to the cooling apparatus 16. The second ends 60 of the conductive members 58 extend through the housing 18 into the interior volume 22 of the cooling apparatus 16. As such the second ends 60 of the conductive members 58 are in direct thermal contact with the first and second liquids 20, 21 within the cooling apparatus 16. The conductive members 58 comprise a high conductive solid material such as pure copper.

In operation, heat is transferred or transported from the computer systems 4 of the data centre 2 to the cooling apparatus 16 by thermal diffusion along the conductive members 58. The second ends 60 of the conductive members 58 act as the heat exchanging apparatus 25 of the cooling apparatus 16 transferring the heat to the first and second liquids 20, 21 within the cooling apparatus 16. The cooling apparatus 16 dissipates the heat maintaining a thermal gradient across the conductive members 58. As such, heat is continually transferred to the cooling apparatus 16, cooling the computer systems 4.

Advantageously, the cooling system 15d of FIG. 9 requires even less control and maintenance than the cooling systems 15a, 15b, 15c depicted in FIGS. 2 to 8. There is no high temperature air 5 nor fluid 52, 55, 56 circulating about a circulation loop 6a, 6b, 6c minimising the number of moving parts as well as negating the need for a pumping system 44 and storage tanks 51. The cooling system 15d of FIG. 9 provides a solid-state solution to transfer the heat from the computer systems 4 to the cooling apparatus 16 as relies simply of thermal diffusion across the conductive members 58.

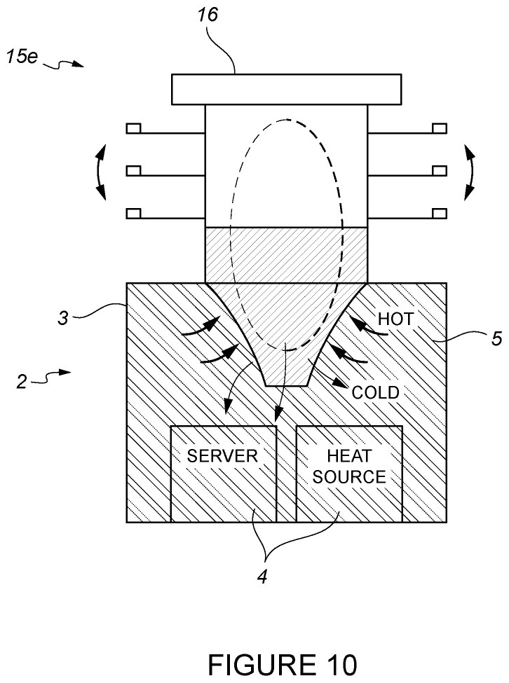

FIG. 10 depicts an alternative cooling system 15e which may comprise the same preferable and optional features as the cooling systems 15a, 15b, 15c, 15d depicted in FIGS. 2 to 9.

Instead of the circulation loops 6a, 6b, 6c of FIGS. 2 and 8 or the conductive members 58 of FIG. 9, the cooling system 15e of FIG. 10 is configured such that a separate component to act as the heat transfer apparatus to transfer heat from the computer systems 4 to the cooling apparatus 16 is not required.

As can be seen from FIG. 10, the cooling apparatus 16 is located upon the roof of the building 3. The first portion 16 of the housing 18 of the cooling apparatus 16 extends into the building 3 such that the first portion 16 is exposed to the high temperature air 5 within the building 3.

The cooling system 15e operates by convection currents in the air contained within the building 3. In operation, the heat from the computer systems 4 located on the floor of the building 3, rises to the roof of the building 3. The housing 18 of the cooling apparatus 16 acts as the heat exchanging apparatus 25 in that the high temperature air 5 transfers heat through the housing 18 to the first liquid 20 located within the housing 18. The heat transferred to the cooling apparatus 16 is dissipated. As such, the high temperature air 5 is cooled and sinks back to the floor of the building 3 where it can absorb heat for the computer systems 4. This process is repeated such that the computer systems 4 are continually cooled.

It will be appreciated that the operation of the cooling system 15e and specifically, the heat dissipation capacity, can be modified by varying the exposure of the cooling apparatus 16 to the high temperature air 5 within the building 3. In other words, if a greater proportion of the cooling apparatus 16 extends within the building 3 such that a greater proportion of the housing 18 is in thermal contact with the high temperature air 5, then the cooling apparatus 16 will absorb more heat. The relative thermal exposure of the cooling apparatus is a parameter that can be optimised according to the characteristics of the specific cooling system 15e.

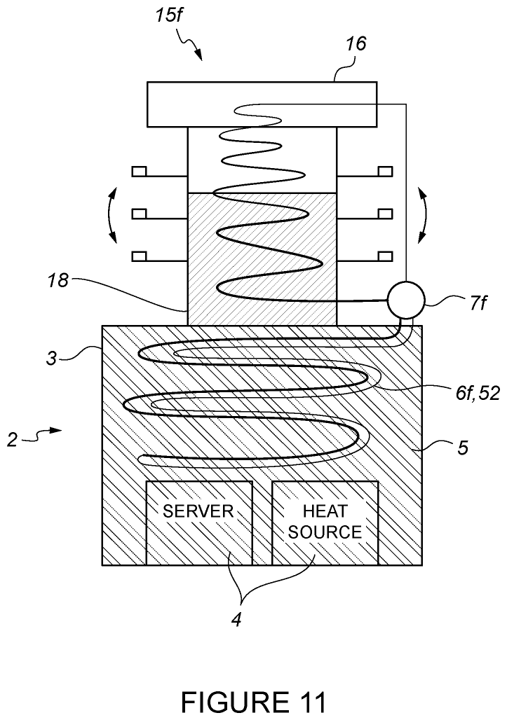

FIG. 11 depicts an alternative cooling system 15f which may comprise the same preferable and optional features as the cooling systems 15a, 15b, 15c, 15d, 15e depicted in FIGS. 2 to 10.

The cooling system 15f of FIG. 11 combines the cooling system 15b of FIG. 7 with the cooling system 15d of FIG. 10.

As can be seen from FIG. 11, a cooling apparatus 16 is located upon the roof of the building 3 like the cooling system 15b of FIG. 10. The housing 18 is exposed to high temperature air 5 from the building 3. The housing 18 acts as a heat exchanging apparatus as heat is transferred from the high temperature air 5 to the cooling apparatus 16.

In addition, the cooling system 15f comprises heat transfer apparatus in the form of a circulation loop 6f sealed within which is a fluid 52. A portion of the circulation loop 6f is located within the building 3 and acts as an additional heat exchanging apparatus. The fluid 52 of the circulation loop 6f absorbs heat from the high temperature air 5. The heated fluid 52 is channeled within the cooling apparatus 16 which cools the heated fluid 52.

The cooling system 15f comprises two mechanisms to transfer heat from the high temperature air 5 to the cooling apparatus 16, namely convection and a circulation loop 6f.

As such, the cooling system 15f advantageously has an improved efficiency of the cooling systems 15b, 15d of FIGS. 7 and 10.

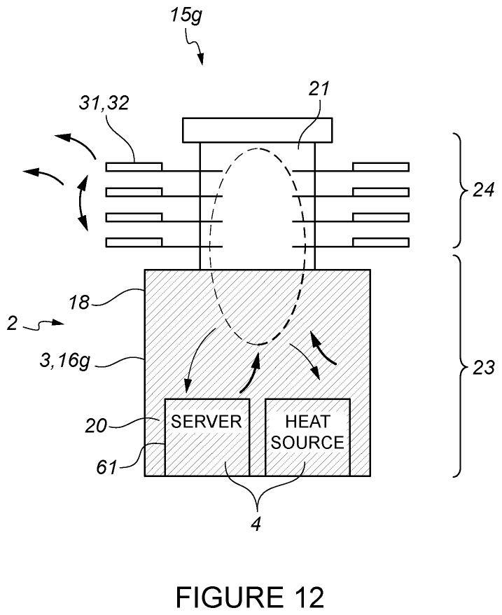

FIG. 12 depicts an alternative cooling system 15g which may comprise the same preferable and optional features as the cooling systems 15a, 15b, 15c, 15d, 15e, 15f depicted in FIGS. 2 to 11.

Instead of the transferring heat from the computer systems 4 housed within a building 3 to a cooling apparatus 16, the building 3 itself is configured to be a cooling apparatus 16g. As such, a heat transfer apparatus is not required. The building 3 houses a first liquid 20 and a second liquid 21. The computer systems 4 and first liquid 20 are located in a first portion 23 of the building 3, towards the base of the building 3, and the second liquid 21 locates within a second portion 24 of the housing 18, above the first liquid 20. The computer systems 4 comprise a fluid tight casing 61 as the computer systems 4 are immersed within the first liquid 20. The fluid tight casing 61 as acts as an interface between the computer systems 4 and the first liquid 20. As such, in this embodiment the heat exchanging apparatus 25 of the cooling system 16 is the fluid tight casing 61. The building 3 further comprises a plurality of independent energy dissipation members 31 such as rods 32.

In operation, the building 3 is fluidly sealed such that the first and second liquids 20, 21 do not leak from the building 3. The building 3 operates as a cooling apparatus 16g in the same way as the cooling apparatus 16 of FIG. 3. The first liquid 20 evaporates to form gaseous bubbles 45 which rise through the building 3 and transfers kinetic and thermal energy to the rods 32. The rods 32 transmit the motion and conduct the thermal energy induced by the gaseous bubbles 45 from the first to second ends 33, 34 and dissipate the energy to the external surroundings of the building 3.

Advantageously, the cooling system 15g is simplified as does not require the heat transfer apparatus to transfer heat from the computer systems 4 to a cooling apparatus 16 as the computer systems 4 are located within the cooling apparatus 16g.

The cooling systems 15a, 15b, 15c, 15d, 15e, 15f, 15g of FIGS. 2 to 12 can cool the high temperature air 5 to the surrounding temperature, for example 20° C. However, these cooling systems 15a, 15b, 15c, 15d, 15e, 15g, 15f cannot cool the high temperature air 5 below the surrounding temperature, 20° C. If the air entering the cooling apparatus 16 was the same temperature as the surroundings, there would be no thermal gradients within the cooling apparatus 16 and heat would not transfer from the air to the first liquid 20.

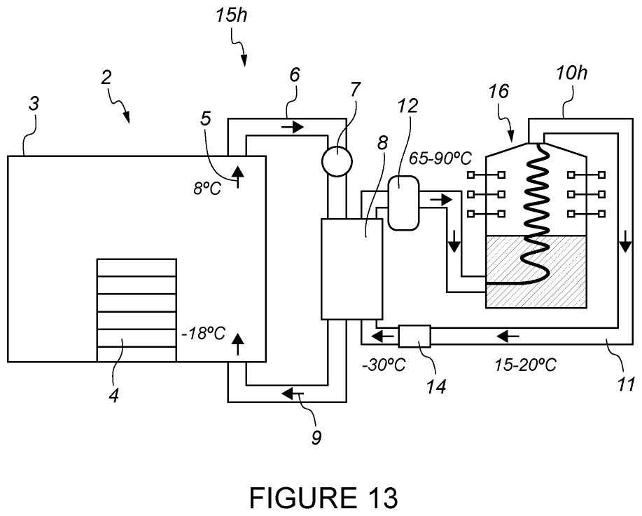

FIG. 13 depicts an alternative cooling system 15h which may comprise the same preferable and optional features as the cooling systems 15a, 15b, 15c, 15d, 15e, 15f, 15g depicted in FIGS. 2 to 12.

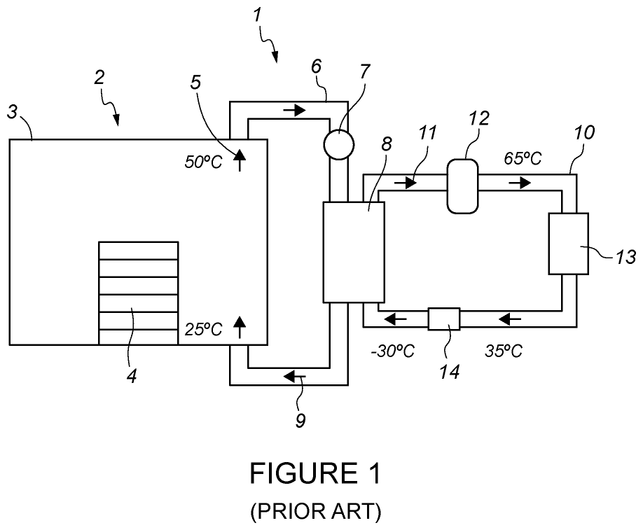

The cooling system 15h of FIG. 13 is similar to the vapour-compression refrigeration system depicted 1 of FIG. 1. However, in contrast to FIG. 1, the refrigeration loop 10h of FIG. 13 comprises a cooling apparatus 16h instead of a condenser 13. The refrigeration loop 10h is the heat transfer apparatus.

The cooling system 15h of FIG. 13 operates in the same way as the cooling system 1 of FIG. 1. However, the cooling apparatus 16 condenses the hot compressed gaseous working fluid 11 back to a liquid instead of a conventional condenser 13.

Advantageously, the cooling system 15h can cool high temperature air 5 to a temperature below ambient temperature without the need to power a condenser. As such, the cooling system 15h of FIG. 13 is cheaper to operate and more environmentally friendly than the vapour-compression refrigeration system 1 known in the art.

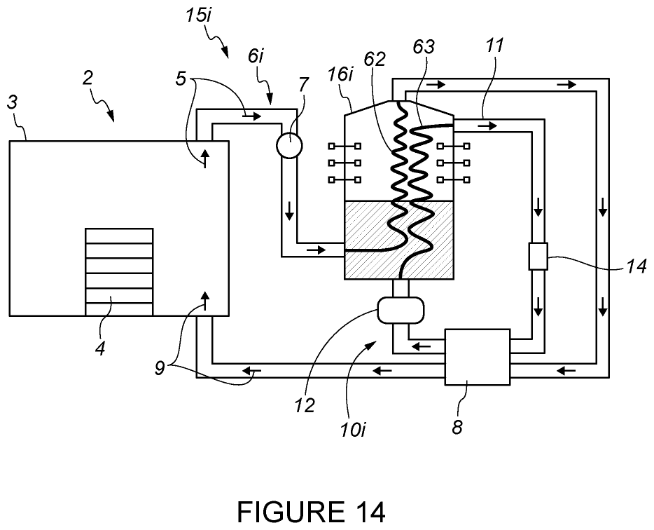

FIG. 14 depicts an alternative cooling system 15i which may comprise the same preferable and optional features as the cooling systems 15a, 15b, 15c, 15d, 15e, 15f, 15g, 15h depicted in FIGS. 2 to 13.

The cooling system 15i of FIG. 14 is a combination of the cooling systems 15b, 15h of FIGS. 2 and 13.

The cooling system 15i of FIG. 14 comprises circulation loop 6i and a refrigeration loop 10i. Both the circulation loop 6i and the refrigeration loop 10i are the heat transfer apparatus. The circulation fan 7i circulates high temperature air 5 from a building 3 about the circulation loop 6i to an evaporator 8. However, in contrast to the embodiment of FIG. 13, the high temperature air 5 is first channeled through the cooling apparatus 16i before it reaches the evaporator 8. The high temperature air 5 is partially cooled by the cooling apparatus 16i. After which, the resulting air is circulated to the evaporator 8 where it is further cooled by the refrigeration loop 10.

The cooling apparatus 16i is also a component of the refrigeration loop 10i of FIG. 14. As such, the cooling apparatus 16i cools both the high temperature air 5 of the circulation loop 6i and the working fluid 11 of the refrigeration loop 10i. The cooling apparatus 16i comprises two heat exchanging apparatus 25, in the form of a first coiled pipe 62 and a second coiled pipe 63. A first coiled pipe 62 forms part of the circulation loop 6i and channels high temperature air 5 through the cooling apparatus 16i. A second coiled pipe 63 forms part of the refrigeration loop 10i and channels working fluid 11 through the cooling apparatus 16i. The high temperature air 5 and working fluid 11 do not mix within the cooling apparatus 16i and more generally the cooling system 15i.

It will be appreciated that thermal capacity of the cooling apparatus 16i is optimised, so that it is sufficiently large to cool both the high temperature air 5 and the working fluid 11. More specifically, the cooling apparatus 16i may be larger and have different first and second fluids 20, 21 in comparison to the cooling systems 15b, 15h of FIGS. 2 and 13.

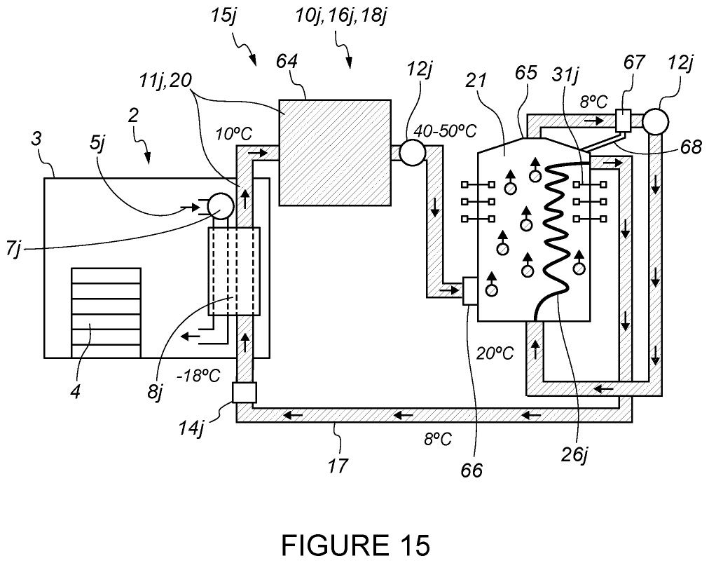

FIG. 15 depicts an alternative cooling system 15j which may comprise the same preferable and optional features as the cooling systems 15a, 15b, 15c, 15d, 15e, 15f, 15g, 15h, 15i depicted in FIGS. 2 to 14.

The cooling system 15j of FIG. 15 comprises a sealed refrigeration loop 10j which contains a working fluid 11j. In the embodiment of FIG. 15, the working fluid 11j also acts as first liquid 20 of a cooling apparatus 16j.

The refrigeration loop 10j comprises an evaporator 8j located in the building 3 of the data centre 2. The evaporator 8j transfers heat from high temperature air 5j (for example 10° C.) within the building 3 to the working fluid 11j of the refrigeration loop 10j inducing a phase change from a liquid to a gas.

The gaseous working fluid 11j circulates to and accumulates in a first chamber 64. The first chamber 64 is fluidly connected to a second chamber 65. Located between the first and second chamber 64, 65 is a compressor 12j and then a relief valve 66. The compressor 12j compresses the gaseous working fluid 11j to a hot liquid working fluid 11j with a temperature, for example, of 40 to 50° C. The relief valve 66 releases the hot liquid working fluid 11j into the second chamber 65. The relief valve 66 controls the flow and pressure of the hot liquid working fluid 11j entering the second chamber 65. The working fluid 11j is compressed before entering the second chamber 65 to increase the heat capacity.

The second chamber 65 comprises a second liquid 21. The second liquid 21 has a lower density but higher boiling point than the liquid working fluid 11j. As the hot liquid working fluid 11j enters the second chamber 65 and mixes with the second liquid 21. The hot liquid working fluid 11j decompresses to a gas and bubbles up through the second chamber 65 dissipating energy to independent energy dissipating members 31j extending through the second chamber 65, as described in the in the context of the cooling apparatus 16 of the 12 first to ninth embodiments of FIGS. 2 to 14. As such, the working fluid 11j acts as the first liquid 20.

The gaseous working fluid 11j is cooled to, for example, to 8° C. The cooled gaseous working fluid 11j is siphoned off the second chamber 65 and further circulated about the refrigeration loop 10j where it is compressed by another compressor 12j increasing the temperature to, for example 20° C. The compressors 12j may also act as pumps to assist with circulating the working fluid 11j about the refrigeration loop 10j. The compressed working fluid 11j is circulated through a coiled pipe 26j extending through the second chamber 65. The coiled pipe 26 acts as a heat exchanging apparatus and transfers heat from the compressed working fluid 11j to the fluids within the second chamber 65 thereby further cooling the working fluid 11f.

The cooled working fluid 11f (8° C.) condenses to a liquid and is circulated back to the building 3 via an expansion valve 14j. The expansion valve 14j reduces the pressure of the cooled working fluid 11f, further reducing the pressure to, for example −38° C. The cold (−38° C.) uncompressed liquid working fluid 11f is recirculated into the evaporator 8j where, by means of thermal diffusion, heat again transfers from the high temperature air 5j to the working fluid 11j. The cycle repeats continually cooling the high temperature air 5j of the building 3 to below ambient temperature.

The housing 18j of the cooling apparatus 16j of FIG. 15 comprises the combination of the first chamber 64, the second chambers 65 and pipes 17 forming the refrigeration loop 10j. The first liquid 20 is also the working fluid 11j and located throughout the refrigeration loop 10j. This embodiment demonstrates the housing 18j of the cooling apparatus 16j does not have to take the form of a unitary chamber and may more generally comprises multiple chambers in combination with connecting pipes. Advantageously, the housing 18 comprising multiple chambers can provide greater flexibility when designing an appropriate cooling apparatus 16 for a specific cooling system 15.

Furthermore, this embodiment also demonstrates the working fluid 11j of a refrigeration loop 10j may also act as the first liquid 20 of a cooling apparatus 16j. Advantageously, this obviates the need for a cooling system 15 to comprise three fluids, namely a working fluid, first liquid and a second liquid when it can operate with two fluids.

As an additional feature, the refrigeration loop 10j of FIG. 15 may comprise a separator 67. The cooled working fluid 11j siphoned off from the second chamber 65 passes through the separator 67 before being further circulated about the refrigeration loop 10j. The separator 67 separates any residual second liquid 21 mixed with the working fluid 11j exiting the second chamber 65. The separated second liquid 21 is channeled back into the second chamber 65 by means of a drain 68. The separator 67 ensures the second liquid 21 is confined to the second chamber 65 and only the working fluid 11j is circulated about the refrigeration loop 10j.

The separator 67 is depicted in FIG. 15 as a separate component of the refrigeration loop 10j, yet it will be appreciated the separator 67 may also take the form as an integral component of the compressor 12j located at the exit of the second chamber 65.

As a further additional feature, the cooling system 15j of FIG. 15 may comprise a circulation fan 7j to draw high temperature air 5j into and through the evaporator 8j. Alternatively, the evaporator 8j may comprise an integral circulation fan to draw high temperature air 5j into and through the evaporator 8j.

The cooling systems 15 of FIGS. 2 to 15 are described as cooling a data centre 2 and specifically, computer systems 4, within a building 3. It will be appreciated that the cooling systems 15 are not limited to cooling a data centre 2 and may be employed to cool any suitable body such as a heat source or building. For example, the cooling systems 15 may be employed to cool an office building or even a chiller room for chilled food products.

### Method of Manufacturing a Cooling Apparatus

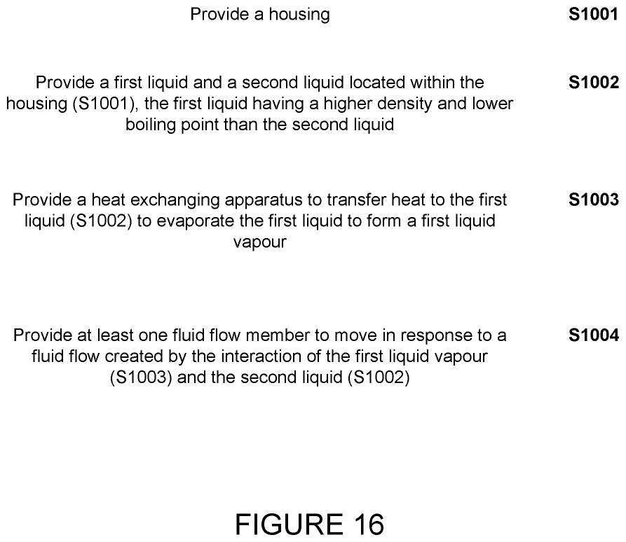

FIG. 16 shows a flow chart for a method of manufacturing the cooling apparatus 16. The method comprises: providing a housing (S1001); providing a first and second liquid located within the housing, the first liquid having a higher density and lower boiling point than the second liquid (S1002); providing a heat transfer apparatus to transfer heat to the first liquid to evaporate the first liquid to form a first liquid vapour (S1003); and providing a plurality of independent energy dissipating members that extend through the housing, wherein the independent energy dissipating member move in response to a fluid flow created by the interaction of the first liquid vapour and second liquid, and transfer heat to a volume external to the housing.

In addition, the method of manufacturing the cooling apparatus 16 may optionally comprise characterising a body which is to be cooled, such as a data centre 2. For example, this may include characterising properties such as the temperature of the body without any cooling, a target temperature of the body with cooling, the temperature variability of the body, the dimensions, shape, composition, location and accessibility of the body.

As a further addition, the method of manufacturing the cooling apparatus 16 may optionally comprise utilising the characteristics of the body to determine the optimum parameters of a cooling apparatus 16. For example, this optimisation process may include determining: the dimensions and shape of the cooling apparatus 16; the volume, relative ratio and chemical composition of the first and second liquids 20, 21; the distribution, orientation, dimensions, design and material composition of the rods 32; if pellets 47 are required, if a condensing loop 48 is required; if a sink 50 is required; if storage tanks 51 are required; the form of the heat exchanging apparatus 25, for example if multiple coiled pipes 26 are required; and how to cooling apparatus 16 is to be integrated into a cooling system. As an example of the parameter dependency, the higher the temperature of the body and the greater the difference between the uncooled temperature of the body and desired cooled temperature of the body, the greater required cooling capacity of the cooling apparatus 16. When choosing the first and second liquids 20, 21 factors such as the heat capacity, relative density and relative boiling points are key considerations. It is advantageous to optimise the cooling apparatus 16 as this ensures the cooling apparatus 16 can operate, in other words, the body will provide enough heat to evaporate any quantity of the first liquid 20. Furthermore, the optimisation ensures the cooling apparatus 16 can operate efficiently.

### Method of Manufacturing a Cooling System

A method of manufacturing a cooling system 15 comprises providing a cooling apparatus 16 in accordance with the flow chart depicted in FIG. 16, as described above, and providing a body, such as a data centre 2 which is to be cooled.

As an additional or alternative feature, the method of manufacturing a cooling system 15 may optionally comprise providing a heat transfer apparatus to transfer heat from the body to the cooling apparatus 16. The heat transfer apparatus may take the form of one or more circulation loops 6 in conjunction with a circulation fan 7 or conductive members 58. In addition, or alternatively, the cooling apparatus 16 may be located above the body such that convection transfers heat from the body to the cooling apparatus 16.

As a further additional or alternative feature, the method of manufacturing a cooling system 15 may optionally comprise providing a refrigeration loop 10. The refrigeration loop 10 operates a thermodynamic cycle known in the art to cool a working fluid 11 below ambient temperature.

The cooling systems 15 disclosed herein have numerous advantages. Various advantageous of each cooling system 15 have been presented. In general, the cooling systems 15 all comprises a cooling apparatus 16 which passively dissipates heat. The cooling apparatus 16 can operate without drawing electrical power and so is financially favourable and environmentally friendly.

Advantageously the cooling apparatus 16 can be incorporated into numerous cooling systems 15. For example, the cooling apparatus 16 can cool air or a fluid in a circulation loop 6. Furthermore, the cooling apparatus 16 can be retrofitted to existing cooling systems such as a vapour-compression refrigeration system by replacing the condenser. In addition, the cooling apparatus 16 is suitable for a cooling system 15 comprising a circulation loop 6 and refrigeration loop 10. The cooling apparatus 16 can cool both the fluid in the circulation loop 6 and the working fluid 11 in the refrigeration loop 10. Such cooling systems 15 are capable of cooling below ambient temperature.

The cooling apparatus 16 does not rely on conventional thermodynamic cycles, but instead provides an alternative mechanism for dissipating heat by utilising a phase change of the first liquid 20 to create fluid flows and the subsequent interaction with the rods 32. The cooling apparatus 16 has minimal moving components, reducing the amount of maintenance that may be required and maximising the lifetime of the device.

Furthermore, the cooling apparatus 16 is scalable as can be adapted for different bodies to be cooled. As such, the dimensions of the cooling apparatus can be adapted to the desired size and resulting expense. The cooling apparatus 16 is a sealed device with minimal moving components so is relatively safe.

The cooling apparatus 16 is customisable as the rods 32, and specifically the conductive surfaces 39 and conductive protrusions 41, can be optimised for a specific cooling system 15.

A cooling apparatus is disclosed. The cooling apparatus comprises a housing, a first liquid and a second liquid located within the housing. The first liquid has a higher density and lower boiling point than the second liquid. The cooling apparatus further comprises a heat exchanging apparatus to transfer heat to the first liquid to evaporate the first liquid to form a first liquid vapour. The cooling apparatus also comprises a plurality of independent energy dissipating members that extend through the housing. These members move in response to a fluid flow created by the interaction of the first liquid vapour and the second liquid and transfer heat to a volume external to the housing. The cooling apparatus can cool a body whilst drawing minimal or even no electrical power. As such the cooling apparatus is environmentally friendly and cheaper to operate.

Throughout the specification, unless the context demands otherwise, the terms “comprise” or “include”, or variations such as “comprises” or “comprising”, “includes” or “including” will be understood to imply the inclusion of a stated integer or group of integers, but not the exclusion of any other integer or group of integers. Furthermore, unless the context clearly demands otherwise, the term “or” will be interpreted as being inclusive not exclusive.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A cooling apparatus comprising:
a housing;
a first liquid and a second liquid located within the housing, the first liquid having a higher density and lower boiling point than the second liquid;
a heat exchanging apparatus to transfer heat to the first liquid to evaporate the first liquid to form a first liquid vapour; and
a plurality of independent energy dissipating members that extend through the housing, wherein the independent energy dissipating members move in response to a fluid flow created by the interaction of the first liquid vapour and the second liquid and transfer heat to a volume external to the housing.

2. The cooling apparatus as claimed in claim 1 wherein, the housing comprises a unitary chamber or two or more chambers with one or more pipes connecting the two or more chambers.

3. The cooling apparatus as claimed in claim 1 wherein, the first liquid is 1-Chloro-3,3,3-trifluoropropene (R1233ZD) and the second liquid is de-mineralised water; or the first liquid is Dichlorotrifluoroethane and the second liquid is de-mineralised water; or the first liquid is 1,2-Dichlorotetrafluoroethane and the second liquid is de-mineralised water; or the first liquid is 1,1,1,3,3,3-Hexafluoropropane and the second liquid is de-mineralised water; or the first liquid is R1234 YF and the second liquid is de-mineralised water; or the first liquid is R-1234ze (Trans-1,3,3,3-tetrafluoroprop-1-ene) and the second liquid is de-mineralised water.

4. The cooling apparatus as claimed in claim 1 wherein, the cooling apparatus comprises three or more liquids.

5. The cooling apparatus as claimed in claim 1 wherein, the heat exchanging apparatus comprises one or more pipes, one or more coiled pipes, a first portion of the housing, one or more conductive members, a fluid tight casing and or an evaporator.

6. The cooling apparatus as claimed in claim 1 wherein, the plurality of independent energy dissipation members is a plurality of rods, a first end of each rod extends into an interior volume of the housing, a second end of each rod extends into a volume external to the housing and a mounting portion of each rod is mounted to the housing.

7. The cooling apparatus as claimed in claim 6 wherein, the plurality of rods is uniformly or non-uniformly distributed about the housing and or orientated perpendicular or non-perpendicular to the housing.

8. The cooling apparatus as claimed in claim 6 wherein, the first end and or second end of each rod of the plurality of rods comprises an enlarged region with at least one conductive surface.

9. The cooling apparatus as claimed in claim 6 wherein, the plurality of rods is uniform or non-uniform in dimension, design and material composition.

10. The cooling apparatus as claimed in claim 1 wherein the cooling apparatus further comprises a condensing loop.

11. The cooling apparatus as claimed in claim 1 wherein the cooling apparatus further comprises a sink.

12. The cooling apparatus as claimed in claim 1 wherein the cooling apparatus further comprises a pumping system and or one or more storage tanks.

13. The cooling apparatus as claimed in claim 1 wherein the cooling apparatus further comprises one or more compressors and or a relief valve and or an expansion valve.

14. A cooling system comprising:
the cooling apparatus as claimed in claim 1; and
a body to be cooled.

15. The cooling system as claimed in claim 14 wherein, the cooling system further comprises a heat transfer apparatus.

16. The cooling system as claimed in claim 15 wherein, the heat transfer apparatus comprises a circulation loop.

17. The cooling system as claimed in claim 16 wherein, the circulation loop comprises: air; or a fluid; or a first loop with a first fluid and a second loop with a second fluid.

18. The cooling system as claimed in claim 15 wherein, the heat transfer apparatus comprises one or more conductive members.

19. The cooling system as claimed in claim 14 wherein the cooling apparatus is located above the body.

20. The cooling system as claimed in claim 14 wherein, the body is the cooling apparatus.

21. The cooling system as claimed in claim 14 wherein, the cooling system further comprises a refrigeration loop with a working fluid.

22. The cooling system as claimed in claim 21 wherein, both the refrigeration loop and circulation loop pass through the cooling apparatus.

23. A method of manufacturing a cooling apparatus comprising,
providing a housing
providing a first liquid and a second liquid located within the housing, the first liquid having a higher density and lower boiling point than the second liquid;
providing a heat exchanging apparatus to transfer heat to the first liquid to evaporate the first liquid to form a first liquid vapour; and
providing a plurality of independent energy dissipating members that extend through the housing, wherein the independent energy dissipating members move in response to a fluid flow created by the interaction of the first liquid vapour and the second liquid and transfer heat to a volume external to the housing.

24. The method of manufacturing a cooling apparatus as claimed in claim 23 wherein, the method further comprises determining the characteristics of a body to be cooled by the cooling apparatus.

25. The method of manufacturing a cooling apparatus as claimed in claim 23 wherein, the method of manufacturing a cooling apparatus comprises determining optimum parameters of a cooling apparatus for use with the body.

26. A method of manufacturing a cooling system comprising,
providing a cooling apparatus in accordance with the method as claimed in claim 23; and
providing a body to be cooled.
